(19) United States
(12) Patent Application Publication
(10) Pub. No.: US 2015/0069492 A1
(43) Pub. Date: Mar. 12, 2015

(54) NONVOLATILE SEMICONDUCTOR MEMORY DEVICE AND METHOD FOR MANUFACTURING THE SAME

(71) Applicant: Kabushiki Kaisha Toshiba, Minato-ku (JP)

(72) Inventor: Kotaro FUJII, Nagasaki-ken (JP)

(73) Assignee: Kabushiki Kaisha Toshiba, Minato-ku (JP)

(21) Appl. No.: 14/164,692

(22) Filed: Jan. 27, 2014

Related U.S. Application Data
(60) Provisional application No. 61/875,752, filed on Sep. 10, 2013.

(51) Int. Cl. H01L 29/788; H01L 29/66

(52) U.S. Cl. CPC H01L 29/788; H01L 29/66825
USPC 257/316; 438/257

(57) ABSTRACT

According to one embodiment, a nonvolatile semiconductor memory device includes semiconductor regions, an element isolation region, control gate electrodes, a floating gate layer, a first insulating film, a second insulating film, a select gate electrode, and a contact electrode. The element isolation region is provided between the semiconductor regions. The control gate electrodes are provided on the semiconductor regions. The floating gate layer is provided in a position where the semiconductor regions and the control gate electrodes cross. The first insulating film is provided between the floating gate layer and the semiconductor regions. The second insulating film is provided between the floating gate layer and the control gate electrodes. The select gate electrode is provided on the semiconductor regions. The contact electrode is disposed on an opposite side of the select gate electrode from the control gate electrodes, and is in contact with one of the semiconductor regions.

### CROSS-REFERENCE TO RELATED APPLICATIONS

This application is based upon and claims the benefit of priority from U.S. Provisional Patent Application 61/875,752, filed on Sep. 10, 2013; the entire contents of which are incorporated herein by reference.

### FIELD

Embodiments described herein relate generally to a nonvolatile semiconductor memory device and a method for manufacturing the same.

### BACKGROUND

In a nonvolatile semiconductor memory device in which a plurality of NAND memory strings are arranged, the spacing between NAND memory strings is becoming narrower and narrower with miniaturization. Hence, the possibility that adjacent NAND memory strings will short-circuit via the contacts connected to the active areas of the NAND memory strings is being increased.

To avoid such a short circuit, there is a method of narrowing the width of the contact connected to the active area. However, this method will cause an open fault between the active area and the contact and an increase in the contact resistance between the active area and the contact.

### BRIEF DESCRIPTION OF THE DRAWINGS

FIG. 1 is a schematic plan view showing a nonvolatile semiconductor memory device according to an embodiment;

FIG. 2A is a schematic cross-sectional view in the position of line A-A′ of FIG. 1, and FIG. 2B is a schematic cross-sectional view in the position of line B-B′ of FIG. 1;

FIG. 3A to FIG. 6B are schematic cross-sectional views showing a manufacturing process of a nonvolatile semiconductor memory device according to the embodiment; and

FIG. 7A to FIG. 7D are diagrams describing an effect of the isotropic etching.

### DETAILED DESCRIPTION

According to one embodiment, a nonvolatile semiconductor memory device includes a plurality of semiconductor regions, an element isolation region, a plurality of control gate electrodes, a floating gate layer, a first insulating film, a second insulating film, a select gate electrode, and a contact electrode. The semiconductor regions extend in a first direction and are arranged in a second direction crossing the first direction. The element isolation region is provided between adjacent regions of the semiconductor regions. The control gate electrodes are provided on an upper side of the semiconductor regions, extend in the second direction, and are arranged in the first direction. The floating gate layer is provided in a position where each of the semiconductor regions and each of the control gate electrodes cross each other. The first insulating film is provided between the floating gate layer and each of the semiconductor regions. The second insulating film is provided between the floating gate layer and each of the control gate electrodes. The select gate electrode is provided on the semiconductor regions via the first insulating film, extends in the second direction, and is disposed at an end of the control gate electrodes arranged. The contact electrode is disposed on an opposite side of the select gate electrode from the control gate electrodes, extends in a third direction from a side of the control gate electrodes toward a side of the semiconductor regions, and is in contact with one of the semiconductor regions. A lower end of the contact electrode is located on a lower side of an upper surface of the semiconductor regions located under the select gate electrode. A portion of the contact electrode is provided on a lower side of a position of the upper surface of the semiconductor regions and has a width wider than a width of the contact electrode at a position of the upper surface in the first direction.

Various embodiments will be described hereinafter with reference to the accompanying drawings. In the following description, identical components are marked with the same reference numerals, and a description of components once described is omitted as appropriate.

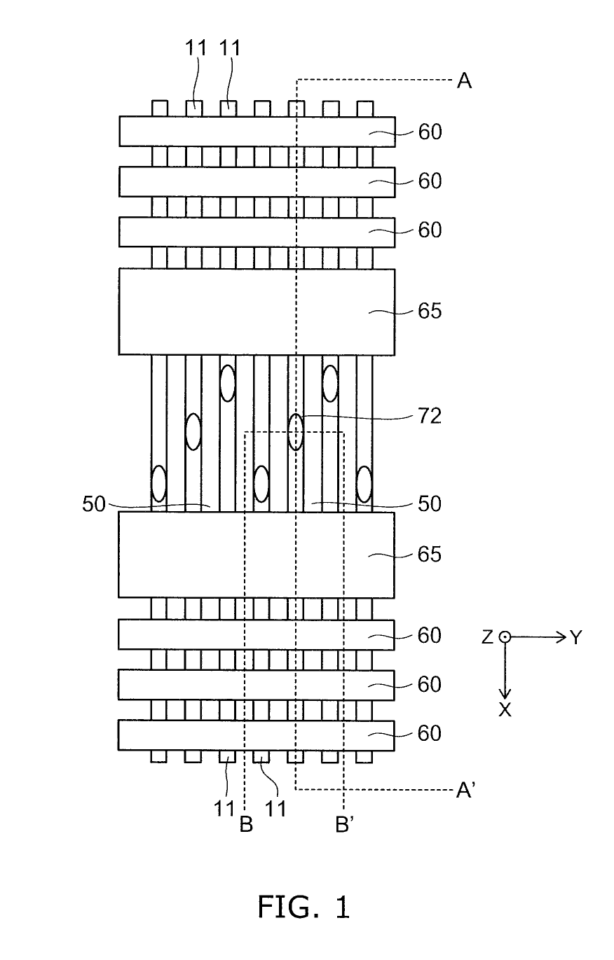

FIG. 1 is a schematic plan view showing a nonvolatile semiconductor memory device according to an embodiment.

A nonvolatile semiconductor memory device 1 according to the embodiment includes a NAND flash memory. The nonvolatile semiconductor memory device 1 includes a semiconductor region 11, a control gate electrode 60, a select gate electrode 65, and a contact electrode 72.

As shown in FIG. 1, in the nonvolatile semiconductor memory device 1, a plurality of semiconductor regions 11 extend in the X-direction (a first direction) and are arranged in the Y-direction (a second direction) crossing (for example, orthogonal to) the X-direction, for example. An element isolation region 50 is provided between semiconductor regions 11. A plurality of control gate electrodes 60 are provided on the upper side of the plurality of semiconductor regions 11. The plurality of control gate electrodes 60 extend in the Y-direction and are arranged in the X-direction. The select gate electrode 65 is disposed at the end of the plurality of control gate electrodes 60 arranged. The select gate electrode 65 extends in the Y-direction.

The contact electrode 72 is connected to one of the plurality of semiconductor regions 11. The contact electrodes 72 are not arranged on a straight line in the Y-direction. For example, in the Y-direction, the plurality of contact electrodes 72 are disposed to be shifted from one another in the X-direction. At the position of the upper surface of the semiconductor region 11, the width of a cross section of the contact electrode 72 taken parallel to the upper surface 11u of the semiconductor region 11 is longer in the X-direction than in the Y-direction. For example, a cross section of the contact electrode 72 taken along the X-Y plane is an ellipse. That is, the X-direction is the major axis of the ellipse, and the Y-direction is the minor axis of the ellipse.

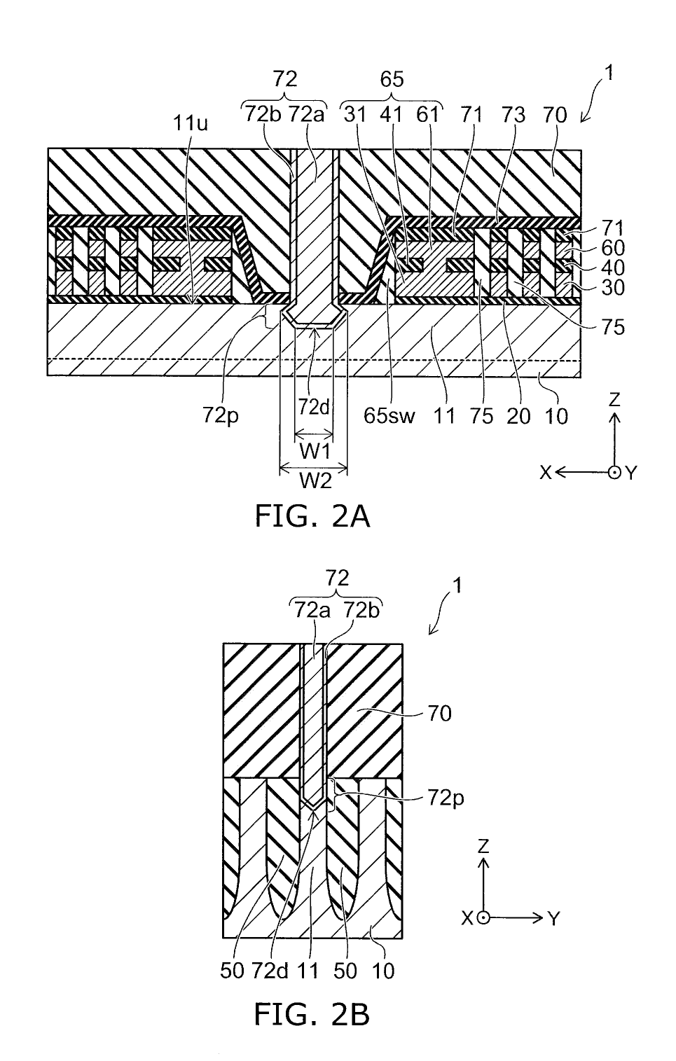

FIG. 2A is a schematic cross-sectional view in the position of line A-A′ of FIG. 1, and FIG. 2B is a schematic cross-sectional view in the position of line B-B′ of FIG. 1.

FIG. 2A and FIG. 2B show cross sections near the select gate electrode of a NAND string.

As shown in FIG. 2A and FIG. 2B, the plurality of semiconductor regions 11 are regions formed by a semiconductor layer 10 being separated by element isolation regions 50, for example. The semiconductor region 11 is an active area that the transistor of the nonvolatile semiconductor memory device 1 occupies. The semiconductor region 11 is a p-type semiconductor region, for example.

As shown in FIG. 2A, a gate insulating film 20 (a first insulating film) is provided on a region of the semiconductor region 11 where elements are arranged. The gate insulating film 20 is provided between a floating gate layer 30 and each of the plurality of semiconductor regions 11. The gate insulating film 20 allows a charge (e.g. electrons) to tunnel between the semiconductor region 11 and the floating gate layer 30.

As shown in FIG. 2A, the floating gate layer 30 is provided in a position where each of the plurality of semiconductor regions 11 and each of the plurality of control gate electrodes 60 cross each other. The floating gate layer 30 is provided on the gate insulating film 20. The floating gate layer 30 can store a charge that has tunneled from the semiconductor region 11 via the gate insulating film 20. The floating gate layer 30 may be referred to as a charge storage layer.

An IPD (inter-poly-dielectric) film 40 (a second insulating film) is provided between the floating gate layer 30 and each of the plurality of control gate electrodes 60. The control gate electrode 60 covers the floating gate layer 30 via the IPD film 40. The control gate electrode 60 functions as a gate electrode that writes a charge on the floating gate layer 30 or reads the charge written in the floating gate layer 30.

The stacked body including the floating gate layer 30, the IPD film 40, and the control gate electrode 60 is referred to as a memory cell.

The select gate electrode 65 is provided at the end of the plurality of control gate electrodes 60 arranged. The select gate electrode 65 is provided on the semiconductor region 11 via the gate insulating film 20. The select gate electrode 65 includes a semiconductor-containing layer 31, a metal-containing layer 61, and an insulating film 41 sandwiched by the semiconductor-containing layer 31 and the metal-containing layer 61.

As shown in FIG. 2A and FIG. 2B, the contact electrode 72 is provided on the opposite side of the select gate electrode 65 from the plurality of control gate electrodes 60. The contact electrode 72 extends in the Z-direction (a third direction) from the side of the plurality of semiconductor regions 11 toward the side of the plurality of control gate electrodes 60. The contact electrode 72 includes a conductive layer 72a and a barrier film 72b.

The lower end 72d of the contact electrode 72 is located on the lower side of the upper surface 11u of the semiconductor region 11 located under the select gate electrode 65. A portion 72p of the contact electrode 72 provided on the lower side of the position of the upper surface 11u has, in the X-direction, a width W2 wider than the width W1 of the contact electrode 72 at the position of the upper surface 11u. For example, at a position between the position of the upper surface 11u and the lower end 72d of the contact electrode 72, the portion 72p of the contact electrode 72 provided on the lower side of the position of the upper surface 11u has a width W2 wider than the width of the contact electrode 72 at the position of the upper surface 11u. The portion 72p of the contact electrode 72 is in contact with the element isolation region 50.

Between adjacent floating gate layers 30 and between the floating gate layer 30 and the select gate electrode 65, the upper side of the semiconductor region 11 forms a diffusion region (a source drain region) in which an n-type impurity is introduced. An n-type impurity is introduced also in the semiconductor region 11 on the lower side of the contact electrode 72, and also this region forms a diffusion region with a high impurity concentration.

An insulating film 71 is provided on each of the plurality of control gate electrodes 60 and on the select gate electrode 65. An interlayer insulating film 75 is provided between adjacent memory cells and between the memory cell and the select gate electrode 65. A side wall film 65sw is provided on the side wall of the select gate electrode 65. An insulating film 73 (a liner film) is provided on the insulating film 71, on the interlayer insulating film 75, on the side wall film 65sw, and on the semiconductor region 11. An interlayer insulating film 70 is provided on the insulating film 73.

The material of the semiconductor layer 10 (or the semiconductor region 11) is a silicon crystal, for example. The material of the gate insulating film 20 is silicon oxide (SiOₓ) or the like, for example.

The IPD film 40 and the insulating film 41 may be a single layer of a silicon oxide film or a silicon nitride film, or a film in which either a silicon oxide film or a silicon nitride film is stacked, for example. For example, the IPD film 40 may be what is called an ONO film (silicon oxide film/silicon nitride film/silicon oxide film).

The material of the floating gate layer 30 and the semiconductor-containing layer 31 is polysilicon (poly-Si) or the like.

The material of the control gate electrode 60 and the metal-containing layer 61 is tungsten, tungsten nitride, or the like, for example.

The material of the conductive layer 72a of the contact electrode 72 contains tungsten, for example, and the material of the barrier film 72b contains titanium nitride.

The insulating film 73 is a stacked film of silicon nitride (Si₃N₄) and silicon oxide (SiO₂), for example.

Other than these, in the embodiment, the material of portions referred to as element isolation regions, insulating films, or insulating layers is silicon oxide (SiO₂), silicon nitride (Si₃N₄), or the like, for example.

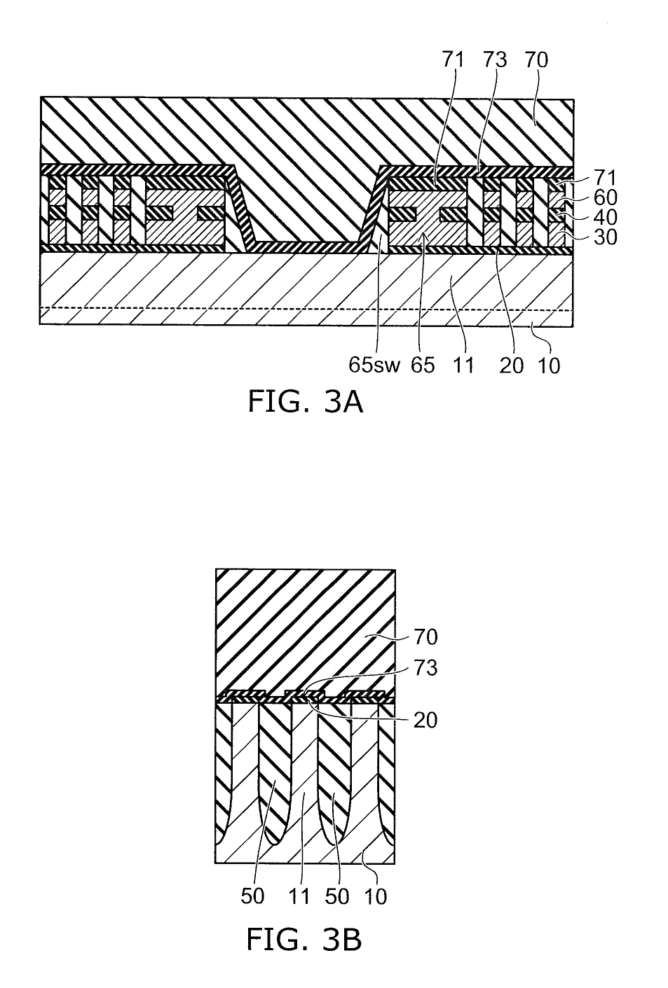

FIG. 3A to FIG. 6B are schematic cross-sectional views showing the manufacturing process of a nonvolatile semiconductor memory device according to the embodiment.

In FIG. 3A to FIG. 6B, the drawings of the numbers including “A” correspond to a cross section taken along line A-A′ of FIG. 1, and the drawings of the numbers including “B” correspond to a cross section taken along line B-B′ of FIG. 1.

First, as shown in FIG. 3A and FIG. 3B, a structure in which memory cells and the select gate electrode 65 are formed on the semiconductor region 11 is prepared. In other words, the memory cells and the select gate electrode 65 shown in FIG. 2A and FIG. 2B are formed on the semiconductor region 11 beforehand. In this stage, the semiconductor region 11, the element isolation region 50, the control gate electrode 60, and the select gate electrode 65 are covered with the interlayer insulating film 70 via the insulating film 73.

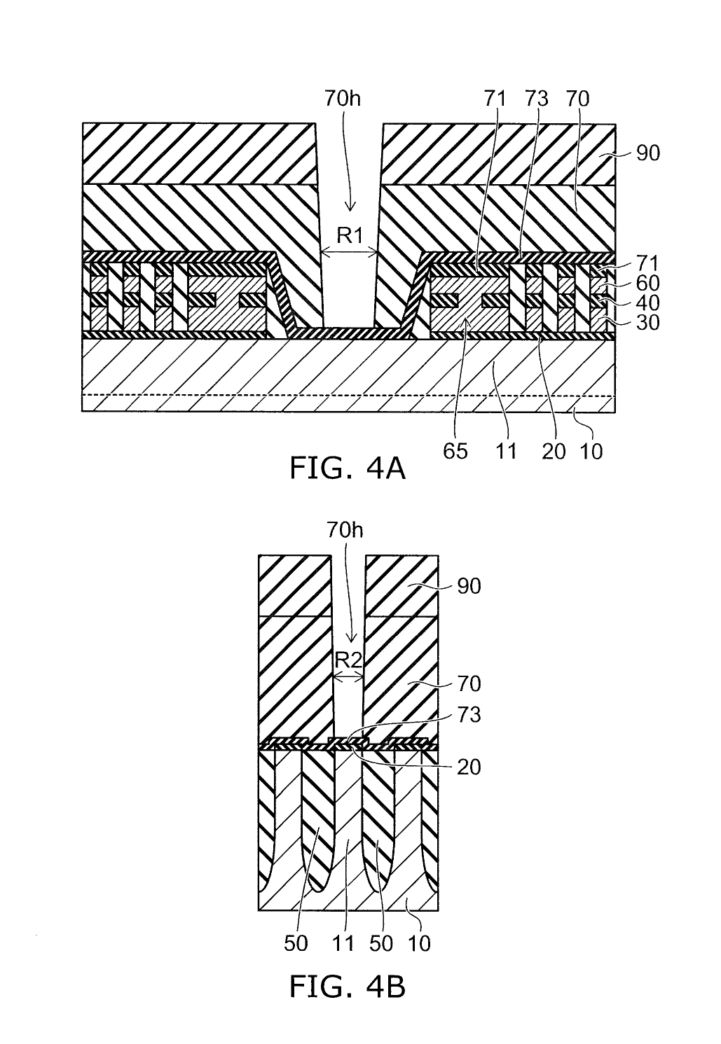

Next, as shown in FIG. 4A and FIG. 4B, a mask layer 90 is patterned on the interlayer insulating film 70. Subsequently, RIE (reactive ion etching) is performed on the interlayer insulating film 70 exposed from the mask layer 90 to form a contact hole 70h on the opposite side of the select gate electrode 65 from the plurality of control gate electrodes 60.

In this stage, the RIE is performed until the insulating film 73 (a liner film) is exposed from the bottom of the contact hole 70h.

After the contact hole 70h is formed, the width in the X-direction or the Y-direction of the contact hole 70h may be adjusted as appropriate using a means for film-forming an insulating film in the contact hole 70h.

In this stage, the contact hole 70h is formed such that when the contact hole is cut parallel to the upper surface 11u of the semiconductor region 11, the inner diameter R1 in the X-direction of the contact hole 70h is longer than the inner diameter R2 in the Y-direction.

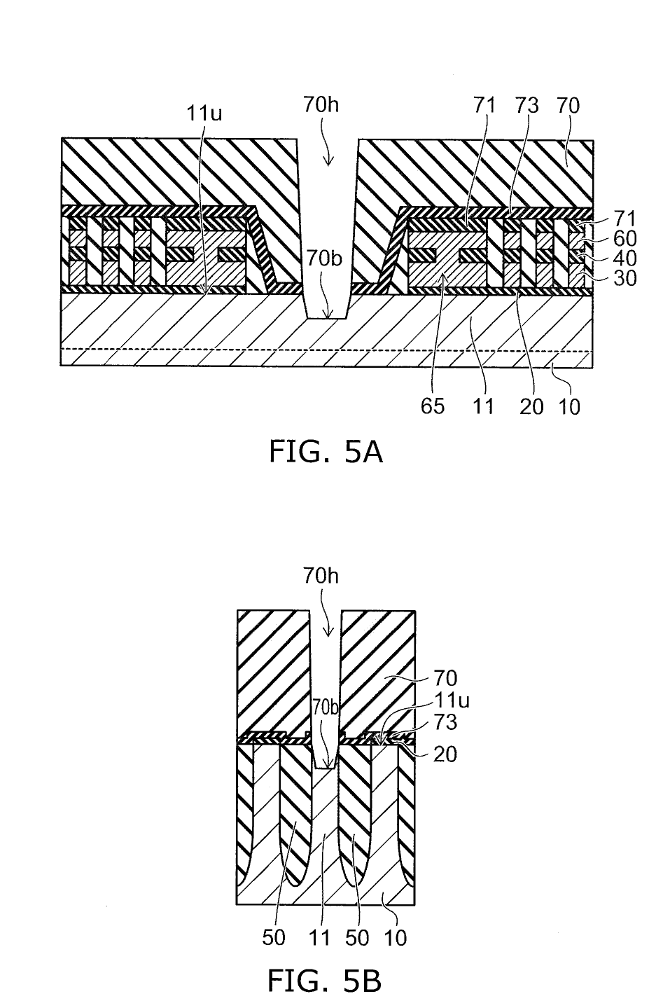

Next, as shown in FIG. 5A and FIG. 5B, the insulating film 73 exposed at the bottom of the contact hole 70h and the semiconductor region 11 under the insulating film 73 are processed by RIE.

After the RIE, the contact hole 70h extends from the surface of the interlayer insulating film 70 to reach the semiconductor region 11. The bottom 70b of the contact hole 70h is located on the lower side of the upper surface 11u of the semiconductor region 11 located under the select gate electrode 65.

In general, a contact hole processed by anisotropic etching has a tapered shape in which its width becomes narrower toward the lower side. Therefore, the width at the bottom 70b of the contact hole 70h is narrower than the width at the position of the upper surface 11u of the semiconductor region 11. In other words, at the position of the upper surface 11u, the width of a cross section of the contact hole 70h taken parallel to the upper surface 11u of the semiconductor region 11 is longer in the X-direction than in the Y-direction. For example, the cross section is an ellipse, and the Y-direction is the minor axis and the X-direction is the major axis. At a position between the position of the upper surface 11u and the lower end 72d of the contact hole 72h, a portion 72p of the contact hole 72h provided on the lower side of the position of the upper surface 11u has a width wider than the width of the contact hole 72h at the position of the upper surface 11u.

Therefore, if from this state the contact electrode 72 is formed in the contact hole 70h, the contact area between the contact electrode 72 and the semiconductor region 11 will be small, and the contact resistance between the contact electrode 72 and the semiconductor region 11 will be high.

In the embodiment, to reduce the contact resistance between the contact electrode 72 and the semiconductor region 11, the processing described below is introduced.

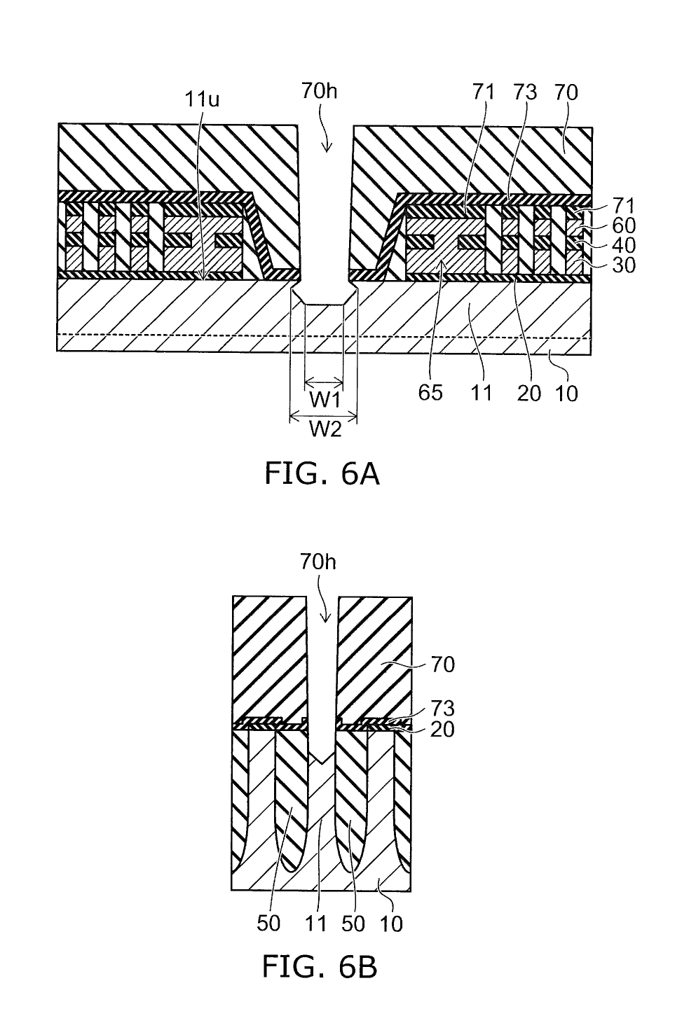

Next, as shown in FIG. 6A and FIG. 6B, the semiconductor region 11 is exposed to a wet etching solution via the contact hole 70h to perform isotropic etching (wet etching) on the semiconductor region 11 exposed at the contact hole 70h.

By the isotropic etching, the volume of the contact hole 70h on the lower side of the upper surface 11u of the semiconductor region 11 becomes larger than that in the state shown in FIG. 5A and FIG. 5B. In other words, in the contact hole 70h on the lower side of the upper surface 11u of the semiconductor region 11, the exposed area of the semiconductor region 11 becomes larger than that in the state shown in FIG. 5A and FIG. 5B.

As the etching solution, a choline aqueous solution (TMY), whereby the etching rate of silicon is higher than the etching rate of silicon oxide, is used. In the isotropic etching, the semiconductor region 11 is exposed to the etching solution until the element isolation region 50 is exposed in the contact hole 70h. In the X-direction, the contact hole 70h has a width W2 wider than the width W1 at the position of the upper surface 11u of the semiconductor region 11.

After that, the barrier film 72b is formed in the contact hole 70h by, for example, the sputtering method, and the conductive layer 72a is formed by CVD (chemical vapor deposition). That is, the contact electrode 72 is formed in the contact hole 70h (see FIGS. 2A and 2B).

By the embodiment, the exposed area of the semiconductor region 11 in the lower portion of the contact electrode 72 is increased by the isotropic etching described above. Thereby, the contact area between the contact electrode 72 and the semiconductor region 11 is increased, and the contact resistance between the contact electrode 72 and the semiconductor region 11 is reduced. Consequently, defective conduction between the contact electrode 72 and the semiconductor region 11 is suppressed.

An advantage of performing the isotropic etching described above will now be described.

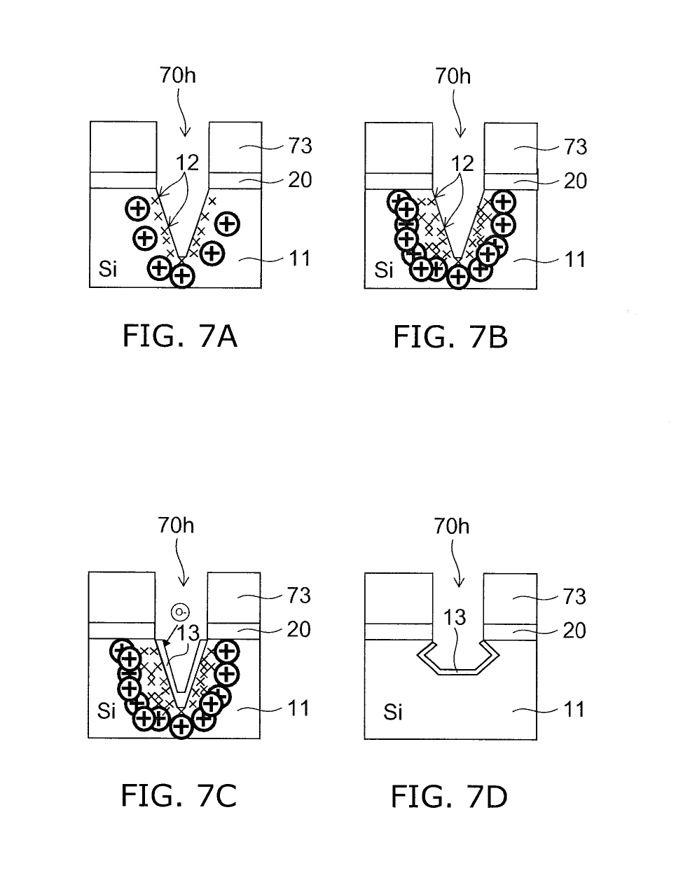

FIG. 7A to FIG. 7D are diagrams describing an effect of the isotropic etching.

After the RIE processing shown in FIG. 5A and FIG. 5B, damage may occur to the Si substrate, for example. FIG. 7A shows this state. In FIG. 7A, the damage is schematically shown by the reference numeral 12. By the RIE, the bond between Si and the impurity element (e.g. arsenic (As)) may be cut, and the vicinity of the exposed surface of the Si substrate may be positively charged.

If plasma processing such as ashing, for example, is performed in this state, the damage 12 to the Si substrate is accelerated to accelerate the positive charging further. FIG. 7B shows this state. If the Si substrate is left in this state, the positive charge will attract oxygen in the air, and a natural oxide film 13 will be formed on the exposed surface of the Si substrate. FIG. 7C shows this state. The film thickness of the natural oxide film 13 becomes thicker as the amount of positive charge carried becomes larger. The thick natural oxide film 13 like this is a factor in the defective conduction between the contact electrode 72 and the semiconductor region 11.

In contrast, as shown in FIG. 7D, when wet etching is performed after the formation of the contact hole 70h, the portion of the damage 12 of the surface of the Si substrate is removed by the wet etching, and the positive charge carried by the Si substrate is terminated by hydrogen, which leads to electrical neutralization. By such neutralization, the film thickness of the natural oxide film 13 stops at a very thin state. In other words, the embodiment reduces the occurrence of the defective conduction between the contact electrode 72 and the semiconductor region 11.

Hereinabove, exemplary embodiments of the invention are described with reference to specific examples. However, the embodiments of the invention are not limited to these specific examples. Those skilled in the art can suitably modify the specific examples by addition of design variation are also encompassed within the scope of the invention as long as they fall within the features of the embodiments. Components and the arrangement, materials, conditions, sizes included in the specific examples described above are not limited to the illustration, however can be modified suitably.

The components included in the embodiments described above can be complexed as long as technically possible, and the combined components are included in the scope of the embodiments to the extent that the features of the embodiments are included. Various other variations and modifications can be conceived by those skilled in the art within the spirit of the embodiments, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device comprising:
a plurality of semiconductor regions extending in a first direction and arranged in a second direction crossing the first direction;
an element isolation region provided between adjacent regions of the plurality of semiconductor regions;
a plurality of control gate electrodes provided on an upper side of the plurality of semiconductor regions, extending in the second direction, and arranged in the first direction;
a floating gate layer provided in a position where each of the plurality of semiconductor regions and each of the plurality of control gate electrodes cross each other;
a first insulating film provided between the floating gate layer and each of the plurality of semiconductor regions;
a second insulating film provided between the floating gate layer and each of the plurality of control gate electrodes;
a select gate electrode provided on the plurality of semiconductor regions via the first insulating film, extending in the second direction, and disposed at an end of the plurality of control gate electrodes arranged; and
a contact electrode disposed on an opposite side of the select gate electrode from the plurality of control gate electrodes, extending in a third direction from a side of the plurality of control gate electrodes toward a side of the plurality of semiconductor regions, and being in contact with one of the plurality of semiconductor regions,
a lower end of the contact electrode being located on a lower side of an upper surface of the semiconductor regions located under the select gate electrode,
a portion of the contact electrode provided on a lower side of a position of the upper surface of the semiconductor regions having a width wider than a width of the contact electrode at a position of the upper surface in the first direction.

2. The device according to claim 1, wherein a portion of the contact electrode provided on the lower side of the position of the upper surface of the semiconductor regions is in contact with the element isolation region.

3. The device according to claim 1, wherein a width of a cross section of the contact electrode taken parallel to the upper surface of the semiconductor regions is longer in the first direction than in the second direction, at the position of the upper surface of the semiconductor regions.

4. The device according to claim 1, wherein the cross section of the contact electrode taken parallel to the upper surface of the semiconductor regions is a ellipse, and the second direction is a minor axis and the first direction is a major axis, at the position of the upper surface of the semiconductor regions.

5. The device according to claim 1, wherein a portion of the contact electrode provided on the lower side of the position of the upper surface of the semiconductor region has a width wider than the width of the contact electrode at the position of the upper surface, at a position between the position of the upper surface and the lower end of the contact electrode.

6. The device according to claim 1, wherein the contact electrode and another contact electrode adjacent to the contact electrode are disposed to be shifted mutually in the first direction, in the second direction.

7. The device according to claim 1, wherein the first direction and the second direction are orthogonal.

8. A method for manufacturing a nonvolatile semiconductor memory device comprising:
forming a plurality of semiconductor regions extending in a first direction and arranged in a second direction crossing the first direction, an element isolation region provided between adjacent regions of the semiconductor regions, a plurality of control gate electrodes provided on an upper side of the semiconductor regions, extending in the second direction, and arranged in the first direction, a floating gate layer provided in a position where each of the semiconductor regions and each of the control gate electrodes cross each other, a first insulating film provided between the floating gate layer and each of the semiconductor regions, a second insulating film provided between the floating gate layer and each of the control gate electrodes, a select gate electrode provided on the semiconductor regions via the first insulating film, extending in the second direction, and disposed at an end of the control gate electrodes arranged, and an interlayer insulating film covering the semiconductor regions, the element isolation region, the control gate electrodes, and the select gate electrode;
forming a contact hole extending from a surface of the interlayer insulating film to reach one of the semiconductor regions on an opposite side of the select gate electrode from the control gate electrodes, a bottom of the contact hole being located on a lower side of an upper surface of the semiconductor regions located under the select gate electrode;
exposing one of the semiconductor regions to an etching solution via the contact hole to perform isotropic etching on the semiconductor regions exposed at the contact hole; and
forming a contact electrode in the contact hole.

9. The method according to claim 8, wherein in the forming the contact hole, the contact hole is formed such that an inner diameter of the contact hole is longer in the first direction than in the second direction when the contact hole is cut parallel to the upper surface of the semiconductor region.

10. The method according to claim 8, wherein in the exposing, one of the semiconductor regions is exposed to the etching solution until the element isolation region is exposed in the contact hole.

11. The method according to claim 8, wherein a width of a cross section of the contact hole taken parallel to the upper surface of the semiconductor regions is longer in the first direction than in the second direction, at a position of the upper surface of the semiconductor region.

12. The method according to claim 8, wherein a cross section of the contact hole taken parallel to the upper surface of the semiconductor region is an ellipse, and the second direction is a minor axis and the first direction is a major axis, at a position of the upper surface of the semiconductor region.

13. The method according to claim 8, wherein a portion of the contact hole provided on the lower side of the position of the upper surface has a width wider than a width of the contact hole at a position of the upper end, at a position between a position of the upper end and a lower end of the contact hole.
